(19) United States
(12) Patent Application Publication
(10) Pub. No.: US 2004/0102033 A1
(43) Pub. Date: May 27, 2004

(54) Method for forming a ternary diffusion barrier layer

(75) Inventors: Jiong-Ping Lu, Richardson, TX (US); Jin Zhao, Plano, TX (US)

Correspondence Address: TEXAS INSTRUMENTS INCORPORATED, P O BOX 655474, M/S 3999, DALLAS, TX, 75265

(73) Assignee: Texas Instruments, Incorporated, Dallas, TX (US)

(21) Appl. No.: 10/301,254

(22) Filed: Nov. 21, 2002

(51) Int. Cl. H01L 21/4763; H01L 21/44

(52) U.S. Cl. 438/627; 438/643

(57) ABSTRACT

The present invention provides, in one embodiment, a method of making thin uniform ternary diffusion barrier layers 150. The method includes introducing first 105, second 135, and third 145 deposition gases one at a time into a chamber 110 to form a conformal ternary layer 150 within an opening 120 located in a dielectric layer 130. Such ternary diffusion barrier layers 150 may be advantageously used in integrated circuit fabrication.

### TECHNICAL FIELD OF THE INVENTION

The present invention is directed, in general, to an integrated circuit and more specifically an improved ternary diffusion barrier layer structure and a method for fabricating the same.

### BACKGROUND OF THE INVENTION

The push toward smaller and faster semiconductor devices has resulted in a shift toward the use of Copper for making electrical interconnections in integrated circuits. For instance, Copper offers a number of benefits over Aluminum or Aluminum-Copper alloys: higher electrical conductivity, good resistance to electro migration, and reduced cross talk and propagation delays at higher interconnect densities. Copper interconnects are not without difficulties, however.

For example, copper atoms can diffuse into dielectric layers in integrated circuits. In particular, copper atoms readily diffuses into silicon-containing dielectric layers, with resultant degradation in the performance of active devices in the integrated circuit. It is therefore necessary to dispose a diffusion barrier layer between a copper interconnect and the dielectric layer.

The requirement of a diffusion barrier layer when using copper-containing vias introduces another problem. Because the barrier layer occupies a portion of the space in the via, the thickness of the copper layer deposited over the barrier layer in the via is reduced. This increases the resistance across the via, which in turn, results in slower active devices. It is desirable therefore to make thin diffusion barrier layers.

The fabrication of certain conventional binary layer materials, such as TiN and TaN, are problematic because they have polycrystalline structures. The polycrystalline structures are thought to provide diffusion pathways for copper atoms between grain boundaries. Such ordered structures can be substantially reduced, however, by using ternary barrier materials comprising three elements, such as TiSiN. Ternary barrier materials are known to have a more amorphous structure that provides greater resistance to diffusion than binary materials such as TiN. The fabrication of ternary barrier layers is problematic, however.

It has proven difficult using conventional methods to produce thin ternary barriers layers that uniformly and conformally coat the via. In particular, there is a tendency for the ternary barrier material to accumulate at the top of the via, thereby restricting the deposition of such material at the bottom of the via. Such vias, when filled with copper, have regions where the thickness of copper is small, which in turn results in even greater resistance and slower active devices. In addition, the performance of active devices containing such vias may be compromised because copper atoms can diffuse into the dielectric layer through portions of the via that were not coated with the ternary barrier layer due to the nonuniformity of the deposition process.

Accordingly, what is needed in the art is a method of making ternary barrier layers that do not exhibit the limitations of the prior art.

### SUMMARY OF THE INVENTION

To address the above-discussed deficiencies of the prior art, the present invention provides a method of making a ternary diffusion barrier in an integrated circuit. The method comprises introducing a flow of a first deposition gas into a chamber to form a conformal layer within an opening located in a dielectric layer, and discontinuing the flow of the first deposition gas. The method also includes introducing a flow of a second deposition gas into the chamber, wherein an element of the second deposition gas diffuses into the conformal layer to form a conformal binary layer. The flow of the second deposition gas is discontinued after the desired time period. The method further includes introducing a flow of a third deposition gas into the chamber, wherein an element of the third deposition gas diffuses into the binary layer to form a conformal ternary layer.

In another embodiment, the present invention provides a method of making an integrated circuit. The method includes forming active devices on a semiconductor substrate and forming interconnect metals lines on a dielectric layer located over the active devices. The method further includes forming via interconnects on the interconnect metal lines, including forming a ternary barrier layer in a via opening by the above-described method.

Still another embodiment is an integrated circuit comprising a via formed in a dielectric layer having a conformal ternary barrier layer formed therein. The conformal ternary barrier layer has a thickness variation of less than about ±20% relative to a thickness of the ternary barrier layer within the via.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIGS. 1A to 1E illustrate sectional views of selected steps in a method of making an exemplary ternary barrier according to the principles of the present invention;

FIGS. 2A to 2C illustrate sectional views of selected steps in a method of making an exemplary integrated circuit according to the principles of the present invention; and

FIG. 3 illustrates a sectional view of components in a partially completed integrated circuit made according to the principles of the present invention.

### DETAILED DESCRIPTION

It has been determined that prior art methods for forming ternary barrier layers are problematic because two or more of the elements comprising the ternary barrier layer are introduced as a gas into a deposition chamber at the same time. Consequently, reactions occur between the elements in the atmosphere above the surface on which the ternary barrier is to be deposited. These pre-deposition reactions can result in the formation of small nanometer-sized droplets or agglomerations in the chamber. When these agglomerations deposit in a via, for example, they accumulate at the via opening, thereby restricting the deposition of a thin uniform barrier layer throughout the via. Thus, methods where two elements, W and Si, are introduced over the same period, will be prone to form agglomerations comprising these two elements, and accumulation of the agglomerations around via openings.

The present invention recognizes for the first time the advantages of making a ternary diffusion barrier by depositing the elements comprising the barrier one element at a time. By doing so, the reactions between elements in an atmosphere above the surfaces where the ternary barrier is being deposited are minimized. As a result, the formation and deposit of agglomerations in the via are also minimized. This facilitates the formation of very thin and uniform barrier layers throughout the entire surface of, for example, a via or contact plug surface. Although the present invention is discussed in the context of forming barrier layers in vias or contact plugs, the ternary barrier layer of the present invention and method of fabrication thereof could be applied to any surface where a diffusion barrier may be used.

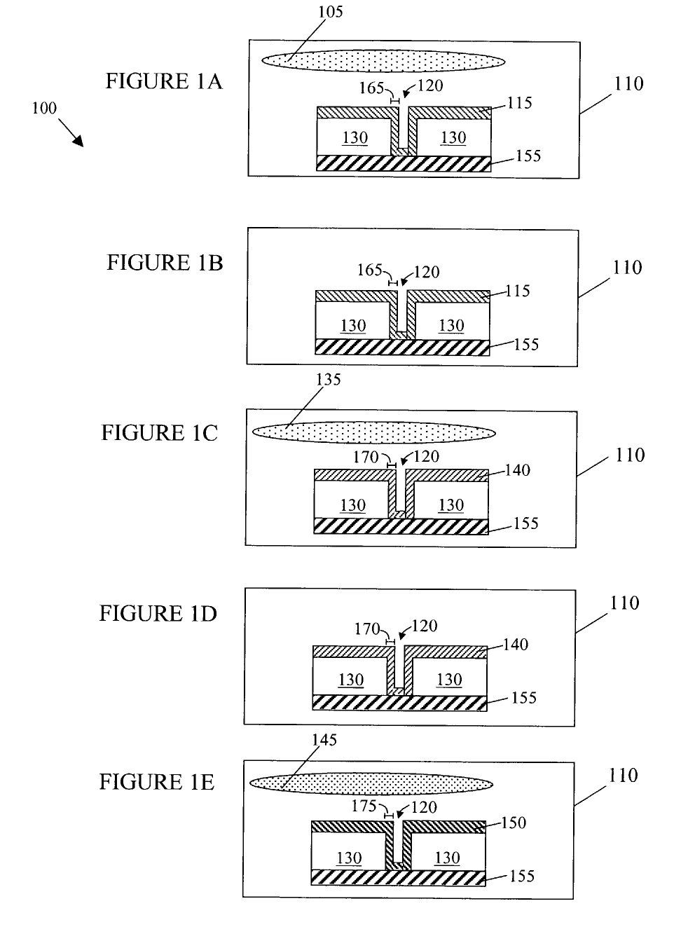

FIGS. 1A to 1E illustrate sectional views of selected steps in a method of making an exemplary ternary barrier 100 according to the principles of the present invention. Turning first to FIG. 1A, illustrated is the introduction of a flow of a first deposition gas 105 into a chamber 110, such as a chemical vapor deposition chamber, to form a conformal layer 115 within an opening 120, such as a via opening, located in a dielectric layer 130. Although the first deposition gas 105 is depicted in a discrete location, one of ordinary skill would understand that the gas 105 and any other gases introduced into the chamber 110 would be distributed throughout the chamber 110. The method further includes discontinuing the flow of the first deposition gas (FIG. 1B).

The ternary diffusion barrier of the present invention may be formed in a conventional CVD chamber including using techniques such as plasma enhanced chemical vapor deposition, or photolytic techniques to increase reactivity. The method of making the integrated circuit 100 may also include providing the substrate 155 that includes a conductive layer and a dielectric layer 130 formed over the substrate 155. Preferably, the conductive layer 155 comprises a metal, such as transition metal, for example, copper or tungsten. It is desirable for the dielectric layer 130 to comprise silicon dioxide, and more desirably, a silicon oxide-based low-k dielectric material containing carbon (SiOC). These structures may be formed using conventional deposition and plasma-enhanced techniques well known to those skilled in the art.

The first deposition gas 105 may contain any compound suitable for depositing an element of the first deposition gas. Preferably, the element of the first deposition gas 105 is a metal, and more preferably a transition metal. More preferably, the transition metal is selected from the group consisting of Titanium, Tantalum, Molybdenum and Tungsten. Such elements are preferred because they have a high melting point, and therefore impart thermal stability to the ternary barrier layer 150, which may be exposed to several subsequent device processing steps that include thermal loads. In addition, these metals form strong covalent bonds with the other elements comprising the ternary barrier layer 150. The ternary barrier layer 150 comprising such transition metals is also strongly associated with the metal comprising the conductive metal layer 155, or metal to be deposited in the opening 120, as well as the dielectric layer 130.

The element of the first deposition gas 105 is also preferably a transition metal that comprises a portion of a volatile compound used in conventional deposition processes, such as CVD. In certain preferred embodiments, for example, the first deposition gas 105 includes tungsten hexafluoride (WF₆) and hydrogen gas. WF₆ is preferred because of its high volatility and ease of delivery through a metering device, such as a mass flow controller, into the chamber 110.

Different compositions of the first deposition gas 105 may be selected depending on whether the ternary barrier layers is being formed in a via or contact level. For example, the first deposition gas may comprise titanium tetra-chloride (TiCl₄) tetra-bromide (TiBr₄) or tetra-iodide (TiI₄), and hydrogen gas. At the contact level, titanium tetra-chloride is preferred over titanium tetra-iodide, because titanium tetra-chloride is a liquid and therefore easier to handle. However, at the via level, titanium tetra-iodide is preferred over titanium tetra-chloride, because titanium tetra-iodide deposition can be carried out at lower temperatures. In other application, titanium tetra-bromide, have intermediate properties between titanium tetra-iodide and titanium tetra-chloride, can be more advantageous. Similar considerations would apply to other first deposition gases, such as tantalum penta-chloride (TaCl₅) versus tantalum penta-bromide (TaBr₅), plus hydrogen gas.

In still other embodiments, the first deposition gas may comprise tungsten hexacarbonyl (W(CO)₆), molybdenum hexacarbonyl (W(CO)₆) or molybdenum hexafluoride (MoF₆), plus hydrogen gas. It may be preferable to use hexacarbonyls in via level applications because carbonyl compounds tend to decompose at the higher temperature used in contact level processing Conversely in contact level applications, it may be preferable to use hexafluorides, which tend to be more thermally stable than carbonyls.

Deposition can be facilitated by plasma enhanced chemical vapor deposition in the presence of an activating gas, such as H-containing plasma. Besides increasing the reactivity of W with the dielectric layer and conducting metal, H₂ plasma also provide a means for removing non-metal components in the volatile compounds. For example, when the first deposition gas 105 includes WF₆, F atoms may be readily removed by the formation of HF gas, thereby avoiding fluoride contamination of the conducting metal 155 or dielectric layer 130.

In certain preferred embodiments, the conformal layer 115 shown in FIG. 1A comprises Tungsten having a thickness 165 of between about 10 and about 200 Angstroms, and more preferably between about 10 and 50 Angstroms. Layers of such thickness 165 may be produced by introducing the first deposition gas 105 for periods, for example, up to about 400 seconds, and more preferably between about 2 and about 20 seconds and at a flow rate ranging from about 2 sccm to about 10 sccm. In certain embodiments, the chamber pressure is between 1 milliTorr and 100 Torr, and more preferably between about 0.10 and about 10 Torr. In other embodiments, the chamber temperature is between about 300 and about 500° C. In embodiments forming barriers at the contact level, temperatures up to about 650° C. are preferred.

Discontinuing the flow of the first deposition gas (FIG. 1B), preferably includes exposing the chamber to a vacuum to remove substantially all of the first deposition gas prior to introducing any other gases such as the second or third deposition gases 135, 145. In certain embodiments, for example, the pressure in the chamber 110 is reduced to about 10⁻⁶ Torr for at least about 2 seconds. The deposition leaves the substantially uniform and conformal layer 115, which, preferably, consists substantially of a single element, such as Tungsten, except for unintended atomic impurities that might be present as associated with any deposition process.

FIG. 1C illustrates introducing a flow of a second deposition gas 135 into the chamber 110. An element of the second deposition gas diffuses into the conformal layer to form a conformal binary layer 140. The method 100 further includes discontinuing the flow of the second deposition gases (FIG. 1D) in a manner similar to that discussed above regarding FIG. 1B. As shown in FIG. 1E, the method 100 also includes introducing a flow of a third deposition gas 145 into the chamber 110, such that an element of the third deposition gas diffuses into the binary layer to form a conformal ternary layer 150.

The element of the second deposition gas 135 (FIG. 1C) may comprise any non-metal element traditionally used in forming conventional ternary diffusion barriers. In certain preferred embodiments, the element of the second deposition gas 135 is Si or B. The element of the second deposition gas 135 may comprise a portion of a volatile compound such as, diborane (B₂H₆), disilane (Si₂H₆), and more preferably silane (SiH₄). In certain embodiments, the ranges of deposition period, flow rates, temperature, and pressure are adjusted to form the binary layer 140 having a thicknesses 170 of between 10 and about 200 Angstroms, and more preferably between about 10 and 50 Angstroms, in a manner similar to that described above. Analogous to that described above for discontinuing the first deposition gas, discontinuing the second deposition gas (FIG. 1D) preferably includes evacuating the chamber 110 to remove substantially all of the first or second deposition gases 105, 135 from the chamber. Preferably, the second deposition gas 135 is discontinued prior to introducing the third deposition gas 145.

The element of the third deposition gas 145 (FIG. 1E) includes nitrogen. The nitrogen may comprise a portion of any conventional compound used in the nitridation of barrier layers. In certain embodiments, for example, the third deposition gas 145 comprises nitrogen (N₂) or ammonia (NH₃) and an optional activating gas such as H₂, and more preferably plasma H₂. The Nitrogen is flowed at a rate ranging from about 10 sccm to about 500 sccm at temperatures ranging from about 300° C. to about 500° C., at pressure ranging from about 0.1 Torr to about 50 Torr and at a wattage ranging from about 50 Watts to about 500 Watts. Plasma enhanced CVD in the presence of H₂ increases the reactivity of nitrogen containing molecule with other elements comprising the ternary barrier layer. For example, when the element of the third deposition gas 145 is N₂, in the presence of plasma, N₂ will be converted to a free radical .N₂ that, in the presence of H radical will become Nitrogen Hydride (NHₓ, x=˜1−3). N itrogen Hydride is highly reactive with silicon and readily forms silicon nitride, or metal silicon nitride. The third deposition gas 145 may be discontinued and any gases remaining in the chamber substantially removed via a vacuum, similar to that discussed above for the first and second deposition gases 105, 135.

In certain advantageous embodiments, the conformal layer 115 is tungsten, the conformal binary layer 140 is tungsten silicide, and the conformal ternary layer 150 is tungsten silicide nitride. It is preferable for these layers to be amorphous layers. In particular, the formation of an amorphous conformal ternary layer 150 is preferred, as this is thought to provide a better diffusion barrier as compared to, for example, a ternary layer with distinct layers comprising different elements of the first, second and third deposition gases.

Several aspects of the present invention facilitate the formation of an amorphous conformal ternary layer 150. The previously mentioned temperature increases during the introduction of the first, second and third deposition gases 105, 135, 145 facilitate the random diffusion of the elements of the first, second and third deposition gases into the conformal, binary conformal and ternary conformal layers 115, 140, 150, respectively. In addition, the presence of plasma enhanced CVD in the presence of H₂ during the separate introduction of the first, second or third elements of the deposition gases also promotes the diffusion of the three elements into the above-mentioned conformal layers at the various stages in the process. Also, the fabrication of thin ternary barrier layers 150, for example, having a thickness 175 of less than about 200 Angstroms, make it more likely that the three elements will be randomly distributed throughout the barrier layer 150 within short periods, for example, less than about 1 minute, to form a substantially amorphous ternary diffusion barrier layer 150.

The method 100 includes making ternary diffusion barriers having a wide range of relative amounts of the first, second and third elements. For example, in certain embodiments, ternary barrier layer 150 is an amorphous layer of first, second and third elements having a relative atomic composition of first:second:third elements, ranging from about 1:0.17:0.08 to about 1:5.9:2.4, and more preferably, ranging from about 1:1:2 to about 1:0.02:1. The elements comprising the ternary barrier layer 150 may also be deposited in any order. For example, in certain embodiments, introducing the third deposition gas 145 includes introducing the third deposition gas prior to introducing the second deposition gas 135.

Moreover, the entire three step deposition cycle may be repeated any number of times to create a thicker, and preferably amorphous, ternary diffusion barrier layer 150. Subsequent deposition cycles may be performed in the same order as the first cycle, or in a different order. For example, in the first cycle, a conformal layer of nitrogen may be deposited first, followed by the deposition of silicon or boron and then the metal. In the second cycle, a conformal layer of silicon may be deposited first, followed by the deposition of nitrogen and then the metal.

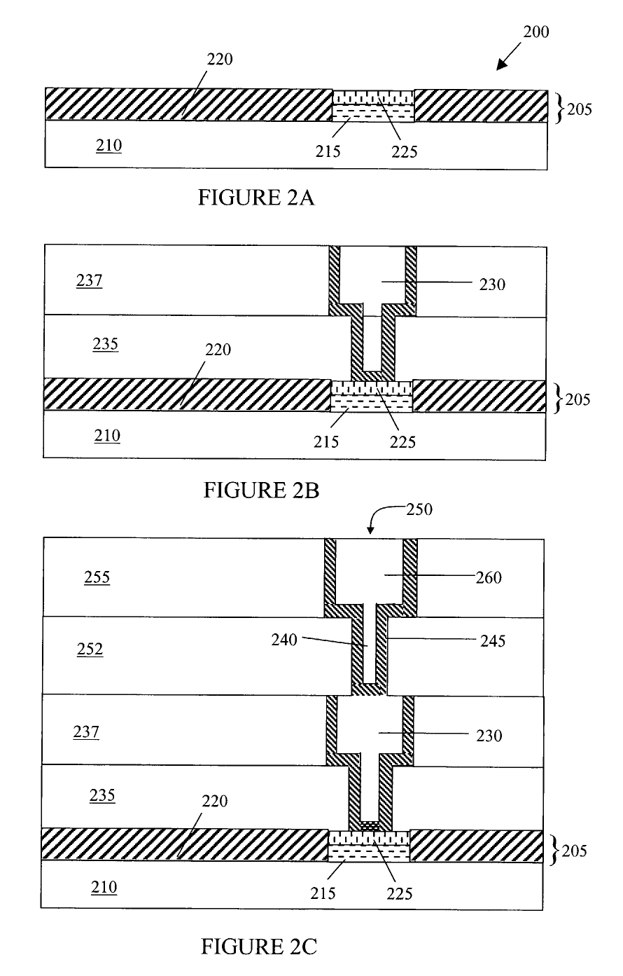

FIGS. 2A-C illustrate another aspect of the present invention, a method 200 of making an integrated circuit at different stages of fabrication. As illustrated in FIG. 2A the method 200 comprises forming active devices 205 on a semiconductor substrate 210. The active device 205 may include conventional MOS integrated circuit components such as a doped region 215 located between field oxide structures 220 and below a gate structure 225. Such structures and their method of fabrication, are more fully discussed, for example, in U.S. Pat. No. 6,245,672 to Hong et al., which is incorporated by reference herein.

FIG. 2B shows forming interconnect metals lines 230 in or on one or more dielectric layers 235, 237 located over the active devices 205. FIG. 2C illustrates forming one or more via interconnects 240 on the interconnect metal lines 230, including forming a ternary barrier layer 245 in a via 250 formed in accordance with the processes discussed above. The via may be formed in or on one or more dielectric layers 252, 255 located over the interconnect metal line 230.

Any of the embodiments of the ternary barrier layer and method of fabrication thereof, as described elsewhere herein, may be incorporated into the method 200 of making an integrated circuit. The method 200 may further include forming via interconnects on the interconnect metal lines by depositing a conducting layer 260 on at least a portion of the ternary barrier layer 245. In certain embodiments, it is desirable for the conducting layer 260 to comprise a metal seed layer formed over the ternary barrier layer and a metal plug formed over the metal seed layer, using procedures well known to those skilled in the art. Preferably, the metal lines 230 and conducting layer 260 comprise transition metals, such as copper.

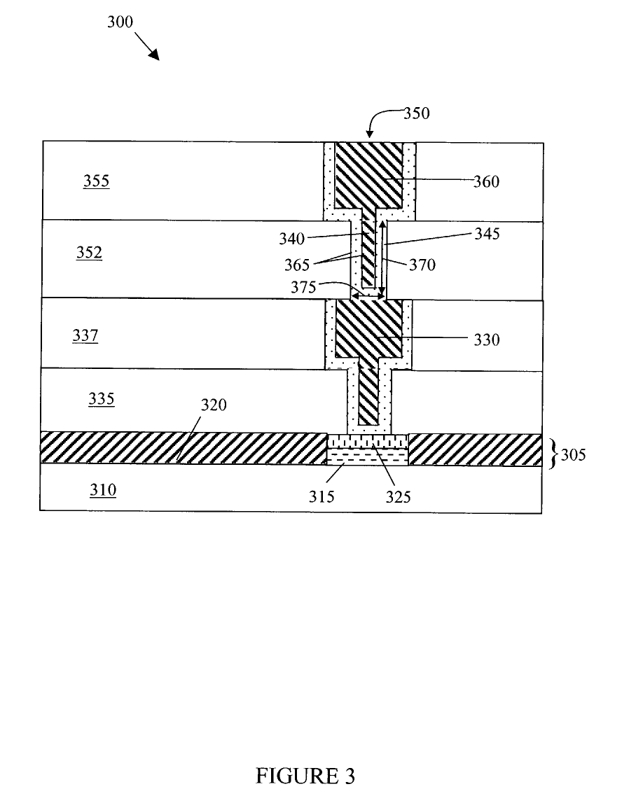

FIG. 3 also illustrates another aspect of the present invention, an integrated circuit 300. FIG. 3 is substantially the same as FIG. 2C, with like numbers being used to identify like structures. The integrated circuit 300 comprises a via 350 formed in one or more dielectric layer 352, 355 having a conformal ternary barrier layer 345 formed therein in a manner discussed above with respect to FIGS. 1A-1E. The conformal ternary barrier layer 345 has a thickness variation of less than about ±20% and more preferably less than ±10%, relative to a thickness 365 of the ternary barrier layer 345 within the via 350. The term thickness as used herein refers to the average thickness of the ternary barrier layer over the full length of the via walls 370. In certain preferred embodiments, for example, the thickness of the ternary barrier layer 360 is between about 10 Angstroms and about 200 Angstroms, more preferably between about 10 and about 100 Angstroms, and even more preferably between about 10 and about 50 Angstroms.

The high uniformity and thickness of the ternary barrier layer 360 of present invention allows the fabrication of vias 350 having very narrow widths 375 and high aspect ratios. In certain advantageous embodiments, for example, the via 350 has an aspect ratio greater than about 4:1, and more preferably greater than about 10:1. The term aspect ratio as used herein refers to the ratio of the height of the via opening 370 divided by the width of the via opening 375. In other advantageous embodiments, the via has a width 375 of less than about 2000 Angstroms, and more preferably less than about 1500 Angstroms and even more preferably less than about 1000 Angstroms.

Having described the present invention, it is believed that the same will become even more apparent by reference to the following example. It should be appreciated that the example are presented solely for the purpose of illustration and should not be construed as limiting the invention. For instance, although the experiments described below may be carried out in laboratory setting, one of ordinary skill in the art could adjust specific numbers, dimensions and quantities up to appropriate values for a full scale plant.

### EXAMPLES

An exemplary range of compositions of ternary barrier layer materials that could be prepared using the processes of the present invention was investigated. Silicon substrates having a layer of W deposited thereon, was placed in a conventional CVD chamber and subjected to one of three processing conditions: 1) exposure to SiH₄ for about 60 s in the presence of plasma H₂ gas, followed by exposure to N₂ and plasma H₂ gas for about 360 s; 2) exposure to SiH₄ for about 240 s in the presence of plasma H₂ gas, followed by exposure to N₂ and plasma H₂ gas for about 360 s; 3) exposure to N₂ and plasma H₂ gas for about 340 s, followed by exposure to SiH₄ for about 240 s in the presence of plasma H₂ gas.

The resulting barrier layers were analyzed by conventional X-Ray Photoelectron Spectroscopy (XPS) to determine the relative Atomic Concentration of Elements. The results, shown in TABLE 1, illustrate that a wide-ranging combination of ternary materials may be prepared using the processes of the present invention.

TABLE 1

| Process | Relative Atomic | Relative Atomic | Relative Atomic |
|---|---|---|---|
| Conditions | Concentration of | Concentration of | Concentration of |
| Number | W | Si | N |
| 1 | 1.0 | 0.89 | 0.28 |
| 2 | 1.0 | 5.90 | 2.40 |
| 3 | 1.0 | 0.17 | 0.08 |

One of ordinary skill in the art would understand how to take such design parameters and construct barrier layers having compositions substantially similar to the predicted profile shown in TABLE 1, using the processes of the present invention, and then incorporate such barrier layers into embodiments of the present invention.

Although the present invention has been described in detail, one of ordinary skill in the art should understand that they can make various changes, substitutions and alterations herein without departing from the scope of the invention.

What is claimed is:

1. A method of making a ternary diffusion barrier in an integrated circuit comprising:
introducing a flow of a first deposition gas into a chamber to form a conformal layer within an opening located in a dielectric layer;
discontinuing said flow of said first deposition gas;
introducing a flow of a second deposition gas into said chamber, an element of said second deposition gas diffusing into said conformal layer to form a conformal binary layer;
discontinuing said flow of said second deposition gas; and
introducing a flow of a third deposition gas into said chamber, an element of said third deposition gas diffusing into said binary layer to form a conformal ternary layer.

2. The method as recited in claim 1, wherein said via is located in said dielectric layer formed over a substrate comprising a conducting layer that includes a transition metal.

3. The method as recited in claim 1, wherein an element of said first deposition gas is selected from the group consisting of:
Titanium;
Tantalum;
Molybdenum; and
Tungsten.

4. The method as recited in claim 1, wherein said first deposition gas includes tungsten hexafluoride and hydrogen gas.

5. The method as recited in claim 1, wherein said element of said second deposition gas is selected from the group consisting of boron and silicon.

6. The method as recited in claim 1, wherein said second deposition gas includes silane.

7. The method as recited in claim 1, wherein said element of said third deposition gas includes nitrogen.

8. The method as recited in claim 1, wherein said conformal layer is tungsten, said conformal binary layer is tungsten silicide, and said conformal ternary layer is tungsten silicide nitride.

9. The method as recited in claim 1, wherein said ternary layer is an amorphous layer of first, second and third elements having a relative atomic composition of said first:second:third elements, ranging from about 1:0.17:0.08 to about 1:5.9:2.4.

10. The method as recited in claim 1, wherein introducing said third deposition gas includes introducing said third deposition gas prior to introducing said second deposition gas.

11. A method of making an integrated circuit comprising:
forming active devices on a semiconductor substrate;
forming interconnect metals lines on a dielectric layer located over said active devices;
forming via interconnects on said interconnect metal lines, including forming a ternary barrier layer in a via opening by:
introducing a flow of a first deposition gas into a chamber to form a conformal layer within a via opening located in a dielectric layer;
discontinuing a said flow of said first deposition gas;
introducing a flow of a second deposition gas into said chamber, an element of said second deposition gas diffusing into said conformal layer to form a conformal binary layer;
discontinuing said flow of said second deposition gas; and
introducing a flow of a third deposition gas into said chamber, an element of said third deposition gas diffusing into said binary layer to form a conformal ternary layer.

12. The method as recited in claim 11, further including depositing a second metal layer on at least a portion of said ternary barrier layer.

13. The method as recited in claim 11 wherein said first and second metal layers comprise a first and second transition metal, respectively.

14. The method as recited in claim 11, wherein an element of said first deposition gas is selected from the group consisting of:
Tungsten;
Titanium;
Tantalum; and
Molybdenum.

15. The method as recited in claim 11, wherein said element of said second deposition gas is selected from the group consisting of boron and silicon.

16. The method as recited in claim 11, wherein said ternary layer is an amorphous layer of first, second and third elements having a relative atomic composition of said first:second:third elements, ranging from about 1:0.17:0.08 to about 1:5.9:2.4.

17. An integrated circuit comprising:
a via formed in a dielectric layer having a conformal ternary barrier layer formed therein, said conformal ternary barrier layer having a thickness variation of less than about ±20% relative to a thickness of said ternary barrier layer within said via.

18. The integrated circuit recited in claim 17, wherein said thickness of said ternary barrier layer is between about 10 Angstroms and about 200 Angstroms.

19. The integrated circuit recited in claim 17, wherein said via has an aspect ratio greater than about 4:1.

20. The integrated circuit recited in claim 17, wherein said via has a width of less than about 2000 Angstroms.
